(19) United States
(12) Patent Application Publication
(10) Pub. No.: US 2016/0336792 A1
(43) Pub. Date: Nov. 17, 2016

(54) POWER CONVERSION SYSTEM, POWER CONVERTER, AND METHOD FOR DIAGNOSING STATE OF POWER STORAGE DEVICE

(71) Applicant: KABUSHIKI KAISHA YASKAWA DENKI, Kitakyushu-shi (JP)

(72) Inventor: Katsushi TERAZONO, Kitakyushu-shi (JP)

(73) Assignee: KABUSHIKI KAISHA YASKAWA DENKI, Kitakyushu-shi (JP)

(21) Appl. No.: 15/222,951

(22) Filed: Jul. 29, 2016

Related U.S. Application Data
(63) Continuation of application No. PCT/JP2014/054194, filed on Feb. 21, 2014.

(51) Int. Cl. H02J 7/02; G01R 31/36; H02J 3/32; H02M 5/42; H01M 10/48; H01M 10/44

(52) U.S. Cl. CPC H02J 7/027; H01M 10/486; H01M 10/44; H02J 7/022; H02J 3/32; H02M 5/42; G01R 31/3662; G01R 31/3679

(57) ABSTRACT

This disclosure discloses a power conversion system including a first power converter, a second power converter, and a power storage device. The second power converter includes a control signal generation part, a detection signal processing part, and a state diagnosis part. The control signal generation part is configured to perform at least one of superposition of a predetermined AC voltage on a DC voltage in a second DC power and superposition of a predetermined AC current on a DC current in the second DC power. The detection signal processing part is configured to detect at least one of a detection value of the DC voltage superposed with the AC voltage and a detection value of the DC current superposed with the AC current. The state diagnosis part is configured to diagnose a state of the power storage device based on the detection value.

### CROSS-REFERENCE TO RELATED APPLICATION

This is a continuation application of PCT/JP2014/054194, filed Feb. 21, 2014, which was published under PCT article 21(2).

### TECHNICAL FIELD

The disclosed embodiment relates to a power conversion system, a power converter, and a method for diagnosing a state of a power storage device.

### BACKGROUND

There is known a method for determining deterioration in a secondary battery, in which a secondary battery to be determined is fitted to an equivalent circuit model by an AC impedance method and the degree of deterioration is determined to be larger as the reciprocal number of a product of a resistance value of a low frequency-side reaction resistance and capacitance of a low frequency-side capacitor is smaller on this occasion.

### SUMMARY

According to one aspect of the disclosure, there is provided a power conversion system. The power conversion system includes a first power converter configured to convert AC power from an AC power source to first DC power, a second power converter configured to convert the first DC power from the first power converter to another second DC power having a different power value from the first DC power, and a power storage device configured to store the second DC power from the second power converter. The second power converter includes a control signal generation part, a detection signal processing part, and a state diagnosis part. The control signal generation part is configured to perform at least one of superposition of a predetermined AC voltage on a DC voltage in the second DC power and superposition of a predetermined AC current on a DC current in the second DC power. The detection signal processing part is configured to detect at least one of a detection value of the DC voltage superposed with the AC voltage and a detection value of the DC current superposed with the AC current. The state diagnosis part is configured to diagnose a state of the power storage device based on at least one of the detection value of the DC voltage and the detection value of the DC current.

### BRIEF DESCRIPTION OF THE DRAWING

FIG. 1 is a block diagram showing an example of configuration of a power conversion system of an embodiment.

FIG. 2 is a circuit diagram showing an example of configuration of a DC-DC converter.

FIG. 3 is a block diagram showing an example of configuration of a first generation part and a second generation part of a control signal generation part, an AC component detection part of a detection signal processing part, and a state diagnosis part.

FIG. 4 is an explanatory view showing an example of wave shapes of various signals.

FIG. 5A is an explanatory view for explaining an equivalent circuit of a power storage device.

FIG. 5B is an explanatory view for explaining an equivalent circuit of a power storage device.

FIG. 5C is an explanatory view for explaining an equivalent circuit of a power storage device.

FIG. 5D is an explanatory view for explaining an equivalent circuit of a power storage device.

FIG. 6A is a graph showing an example of a Bode plot.

FIG. 6B is a graph showing an example of a Bode plot.

FIG. 7 is a graph showing an example of a Nyquist plot.

FIG. 8 is a flow chart showing a control procedure by a method for diagnosing a state of a power storage device executed by the DC-DC converter.

FIG. 9 is a block diagram showing a configuration example of the DC-DC converter.

### DESCRIPTION OF THE EMBODIMENTS

Hereinafter, one embodiment will be explained while referring to the drawings.

### <Configuration Example of Power Conversion System>

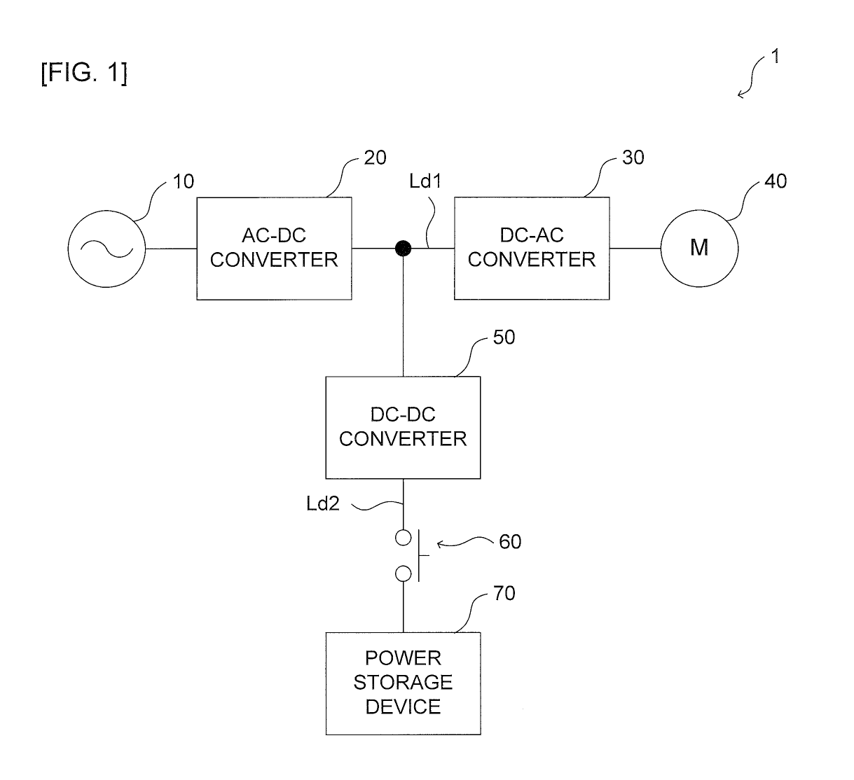

First, while referring to FIG. 1, an example of configuration of a power conversion system of the embodiment will be explained.

As shown in FIG. 1, a power conversion system 1 of the embodiment has an AC-DC converter 20, a DC-AC converter 30, a DC-DC converter 50, a power storage device 70, and a circuit breaker 60.

The AC-DC converter 20 converts AC power supplied from an AC power source 10 (for example, a system power source) to predetermined DC power (corresponds to an example of first DC power, hereinafter, it is also called “first DC power”). Then, the AC-DC converter 20 outputs the first DC power to the DC-AC converter 30 and the DC-DC converter 50 via a DC line Ld1 (hereinafter, it is also called a “first DC line Ld1”) between the AC-DC converter 20 and the DC-AC converter 30. That is, the AC-DC converter 20 corresponds to an example of a first power converter.

The DC-AC converter 30 converts the first DC power supplied via the first DC line Ld1 to predetermined AC power, and outputs the same to an AC motor 40 being a load.

The AC motor 40 operates based on AC power supplied from the DC-AC converter 30.

Meanwhile, in the embodiment, explanation will be given while taking an instance that a load is the AC motor 40 as an example, but the load is not limited to the AC motor 40 and is not limited particularly only if it is an electronic device that operates based on AC power. Furthermore, the load is not limited to the electronic device that operates based on AC power, but may be an electronic device that operates based on DC power. In the case where the load is the electronic device that operates based on DC power (for example, a DC motor), a power conversion system may be configured so that the electronic device operates based on the first DC power supplied via the first DC line Ld1

The DC-DC converter 50 converts the first DC power supplied from the AC-DC converter 20 via the first DC line Ld1 to another DC power (which corresponds to an example of second DC power, hereinafter it is also called “the second DC power”) having a different power value (for example, having a lower power value). Then, the DC-DC converter 50 outputs the second DC power to the power storage device 70 via a DC line Ld2 (hereinafter, it is also called a “second DC line Ld2”) between the DC-DC converter 50 and the power storage device 70. That is, the DC-DC converter 50 corresponds to an example of a power converter and a second power converter. Further, the DC-DC converter 50 may convert the second DC power supplied from the power storage device 70 via the second DC line Ld2 to the first DC power (for example, having a higher power value), and output the same to the DC-AC converter 30 via the first DC line Ld1.

The power storage device 70 stores (charges) the second DC power supplied from the DC-DC converter 50 via the second DC line Ld2. Further, the power storage device 70 may also output (discharge) the stored second DC power to the DC-DC converter 50 via the second DC line Ld2.

As the power storage device 70, it is not particularly limited only if it is a device capable of charging/discharging the second DC power, and, for example, one or more secondary batteries (also called a “storage battery” or a “charging type battery”), one or more capacitors (also called an “electric condenser” or a “capacitor”), one or more fuel cells or the like are used. On this occasion, as the secondary battery, for example, a lithium ion secondary battery, a nickel-hydrogen storage battery, a nickel-cadmium storage battery, a lead storage battery, a sodium-sulfur battery or the like is used. As the capacitor, for example, an electric double layer capacitor, a lithium ion capacitor or the like is used. In the embodiment, however, an instance that the power storage device 70 is one lithium ion secondary battery will be explained.

The circuit breaker 60 is disposed on the second DC line Ld2. The circuit breaker 60, when obtaining an abnormality diagnosis signal (to be described later) from the DC-DC converter 50, may break and disconnect the connection between the DC-DC converter 50 and the power storage device 70 by performing a breaking operation in accordance with the abnormality diagnosis signal.

Meanwhile, in the embodiment, explanation will be given while taking the power conversion system 1 in which the circuit breaker 60 is disposed on the second DC line Ld2 as an example, but it may also be applied to a power conversion system in which the circuit breaker 60 is not disposed on the second DC line Ld2.

Hereinafter, the outline of operation of the power conversion system 1 will be explained.

That is, there is such an occasion that AC power within a predetermined range of power value is supplied to the AC-DC converter 20 from the AC power source 10. On this occasion, the AC-DC converter 20 converts the AC power to the first DC power of a predetermined power value, and outputs the same to the DC-AC converter 30 and the DC-DC converter 50 via the first DC line Ld1. The DC-DC converter 50 converts the first DC power of a predetermined power value supplied from the AC-DC converter 20 via the first DC line Ld1 to the second DC power, outputs the same to the power storage device 70 via the second DC line Ld2 and causes the power storage device 70 to execute a charge operation (absorption of charges).

On the other hand, there is such an occasion that a voltage value of AC power supplied to the AC-DC converter 20 from the AC power source 10 has fallen below a predetermined range of the power value. On this occasion, the power value of the first DC power output to the DC-AC converter 30 and the DC-DC converter 50 from the AC-DC converter 20 via the first DC line Ld1 lowers and a state where it does not reach a predetermined power value is brought about. In the state, the DC-DC converter 50 causes the power storage device 70 to execute a discharge operation (release of charges), converts the second DC power supplied from the power storage device 70 via the second DC line Ld2 to the first DC power, and outputs the same to the DC-AC converter 30 via the first DC line Ld1. As a result, the DC-DC converter 50 raises the power value of the first DC power to be supplied to the DC-AC converter 30 via the first DC line Ld1 so as to approach the predetermined power value. Consequently, even an occasion arises that the voltage value of AC power to be supplied to the AC-DC converter 20 from the AC power source 10 falls below a predetermined range of power value, supply of the first DC power of the predetermined power value to the DC-AC converter 30 may be continued.

Meanwhile, needless to say, the configuration and operation of the power conversion system 1 are not limited to the content, but may be another content.

Here, the power storage device 70 may change in the state such as deterioration by repetition of charge/discharge or sudden occurrence of an abnormality (such as short circuit) in the middle of repetition of charge/discharge, and, therefore, it becomes important to diagnose and grasp the state of the power storage device 70. For example, in a lithium ion secondary battery, by repeating charge/discharge, heavy metal such as cobalt on the electrode surface induces a chemical reaction and, in the part, a thin film that hardly allows lithium ions to pass through is produced. The film blocks going in and out of lithium ions and hinders smooth movement, which becomes a barrier of charge/discharge to thereby bring about deterioration of the lithium ion secondary battery.

In the embodiment, the DC-DC converter 50 that supplies the second DC power to the power storage device 70 has a function of diagnosing a state of the power storage device 70.

### <Configuration Example of DC-DC Converter>

Hereinafter, an example of configuration of the DC-DC converter 50 will be explained.

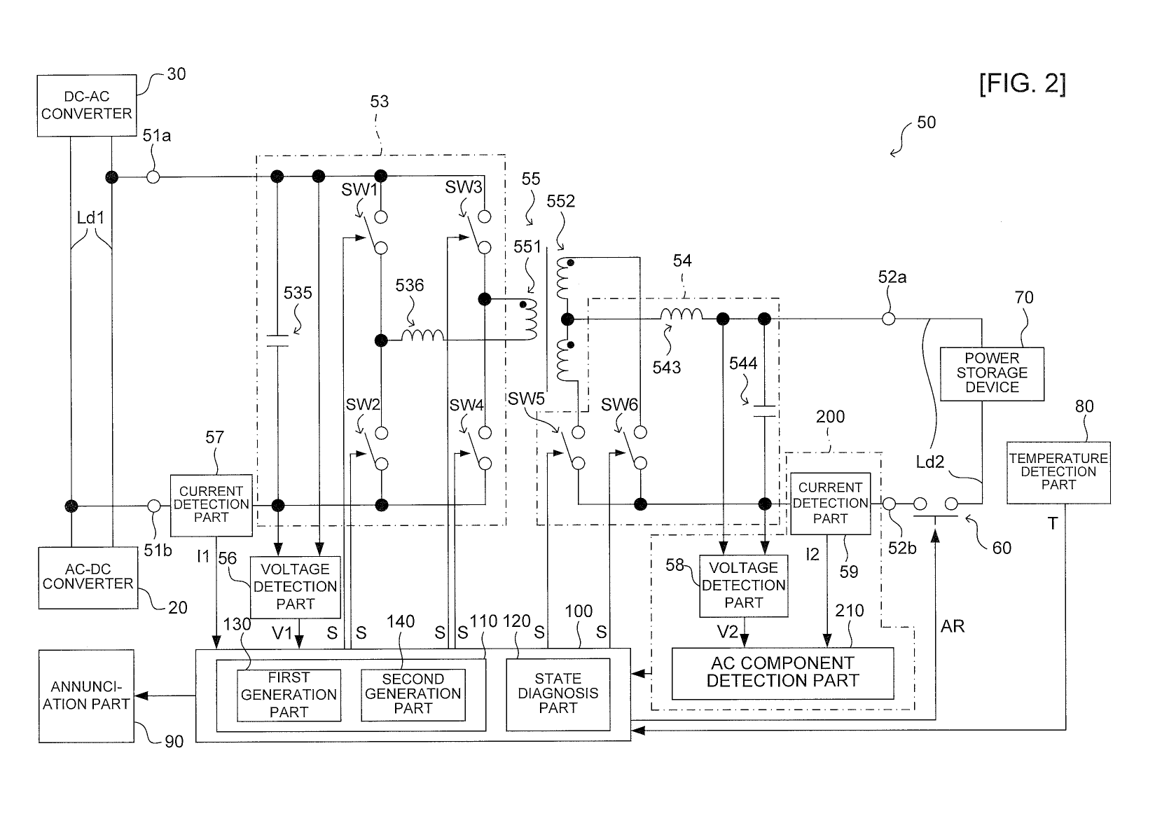

The DC-DC converter 50 performs at least one of superposition of a predetermined AC voltage on a DC voltage (hereinafter, it is also called a “second DC voltage”) in the second DC power and superposition of a predetermined AC current on a DC current (hereinafter, it is also called a “second DC current”) in the second DC power. Subsequently, the DC-DC converter 50 detects at least one of a detection value V2 of the DC voltage (see FIG. 2 etc. to be described later, hereinafter it is also called a “second DC voltage detection value V2”) superposed with the AC voltage and a detection value I2 of the DC current (see FIG. 2 etc. to be described later, hereinafter it is also called a “second DC current detection value I2”) superposed with the AC current. Then, the DC-DC converter 50 diagnoses a state of the power storage device 70 based on at least one of the second DC voltage detection value V2 and the second DC current detection value I2. Hereinafter, while referring to FIG. 2, regarding the configuration of the DC-DC converter 50, an example implemented with a functional block will be explained more concretely.

Here, in an instance that the power storage device 70 is a capacitor such as an electric double layer capacitor, etc., as the DC-DC converter 50, either of an insulation type and non-insulation type DC-DC converters may be used. However, in the embodiment in which the power storage device 70 is a lithium ion secondary battery, as the DC-DC converter 50, the insulation type DC-DC converter is suitably used. Accordingly, in the embodiment, an instance that the DC-DC converter 50 is the insulation type DC-DC converter will be explained.

As a power conversion system of the insulation type DC-DC converter, there are various systems such as an RCC system, a push-pull system, a half bridge system and a full bridge system. As the power conversion system of the DC-DC converter 50, any system is acceptable, and, in the embodiment, an instance that the power conversion system of the DC-DC converter 50 is the full bridge system will be explained.

As shown in FIG. 2, the DC-DC converter 50 has a control part 100 including first terminals 51a, 51b, second terminals 52a, 52b, a transformer 55, a first conversion part 53, a second conversion part 54, a voltage detection part 56, a current detection part 57, a control signal generation part 110 and a state diagnosis part 120, and a detection signal processing part 200. Further, the power conversion system 1 has, in addition to the configuration explained above, a temperature detection part 80 and an annunciation part 90.

The first terminals 51a, 51b are connected to the first DC lines Ld1, Ld1. Further, the second terminals 52a, 52b are connected to the second DC lines Ld2, Ld2.

The transformer 55 includes a first winding 551 and a second winding 552 electrically insulated from each other. On the second winding 552, a center tap is disposed. Meanwhile, needless to say, the configuration of the transformer 55 is not limited to the content, but may be another content.

The first conversion part 53 is disposed between the first terminals 51a, 51b and the first winding 551. The first conversion part 53 includes a capacitor 535, four semiconductor switches SW1, SW2, SW3, SW4, and a reactor 536.

The capacitor 535 is connected between the first terminals 51a, 51b.

The semiconductor switches SW1-SW4 are each configured, for example, by connecting a semiconductor switching element and a diode in reversely parallel, and are connected in the full bridge type. Among these, the semiconductor switches SW1, SW2 are connected in series with each other, and a series circuit of these semiconductor switches SW1, SW2 is connected between the first terminals 51a, 51b. Further, to a connection point of the semiconductor switches SW1, SW2, one end of the reactor 536 is connected. Furthermore, the semiconductor switches SW3, SW4 are connected in series with each other, and a series circuit of these semiconductor switches SW3, SW4 is connected between the first terminals 51a, 51b in a parallel state with the series circuit of the semiconductor switches SW1, SW2. To a connection point of the semiconductor switches SW3, SW4, one end of the first winding 551 is connected.

The reactor 536 has one end thereof connected to the connection point of the semiconductor switches SW1, SW2, and has the other end thereof connected to the other end of the first winding 551.

Meanwhile, needless to say, the configuration of the first conversion part 53 is not limited to the content, but may be another content.

The second conversion part 54 is disposed between the second terminals 52a, 52b and the second winding 552. The second conversion part 54 has two semiconductor switches SW5, SW6, a reactor 543, and a capacitor 544.

The semiconductor switches SW5, SW6 are each configured, for example, by connecting a semiconductor switching element and a diode in reversely parallel, and are connected via the second winding 552. Of these, the semiconductor switch SW5 has one terminal thereof connected to the second terminal 52b, and has the other terminal thereof connected to one end of the second winding 552. On the other hand, the semiconductor switch SW6 has one terminal thereof connected to a second terminal 52b, and has the other terminal thereof connected to the other end of the second winding 552.

The reactor 543 has one end thereof connected to a center tap of the second winding 552, and has the other end thereof connected to the second terminal 52a.

The capacitor 544 is connected between the other end of the reactor 543 and the second terminal 52b.

Meanwhile, needless to say, the configuration of the second conversion part 54 is not limited to the content, but may be another content.

Further, since the power conversion operation (a step-down operation and a step-up operation) by the DC-DC converter 50 is a known operation, detailed explanation is omitted.

The voltage detection part 56 is connected to a middle of a terminal of the capacitor 535 on the first terminal 51a side and a terminal of the semiconductor switch SW1 on the first terminal 51a side, and to a terminal of the capacitor 535 on the first terminal 51b side. The voltage detection part 56 detects a voltage between the two connection points as a voltage at least including a DC voltage in the first DC power (hereinafter, it is also called a “first DC voltage”), and outputs the same as a DC voltage detection value V1 (hereinafter, it is also called a “first DC voltage detection value V1”) to the control part 100.

The current detection part 57 is disposed between the first terminal 51b and a terminal of the capacitor 535 on the first terminal 51b side. The current detection part 57 detects a current in a setting place thereof as a current at least including a DC current in the first DC power (hereinafter, it is also called a “first DC current”), and outputs the same as a DC current detection value I1 (hereinafter, it is also called a “first DC current detection value I1”) to the control part 100.

The temperature detection part 80 is implemented, for example, by an NTC thermistor, a PTC thermistor or the like, detects temperature in a setting place thereof (for example, vicinity of a screw terminal part of the power storage device 70, etc.) as the temperature of the power storage device 70, and outputs the same as detection temperature T to the control part 100.

The annunciation part 90 is implemented, for example, by a monitor, a lamp, a buzzer, a speaker or the like, and performs annunciation based on a diagnosis result of the state diagnosis part 120 (details will be described later).

### <Outline of Control Signal Generation Part, Detection Signal Processing Part, and State Diagnosis Part>

Next, the outline of the control signal generation part 110, the detection signal processing part 200 and the state diagnosis part 120 being the principal parts of the embodiment will be explained.

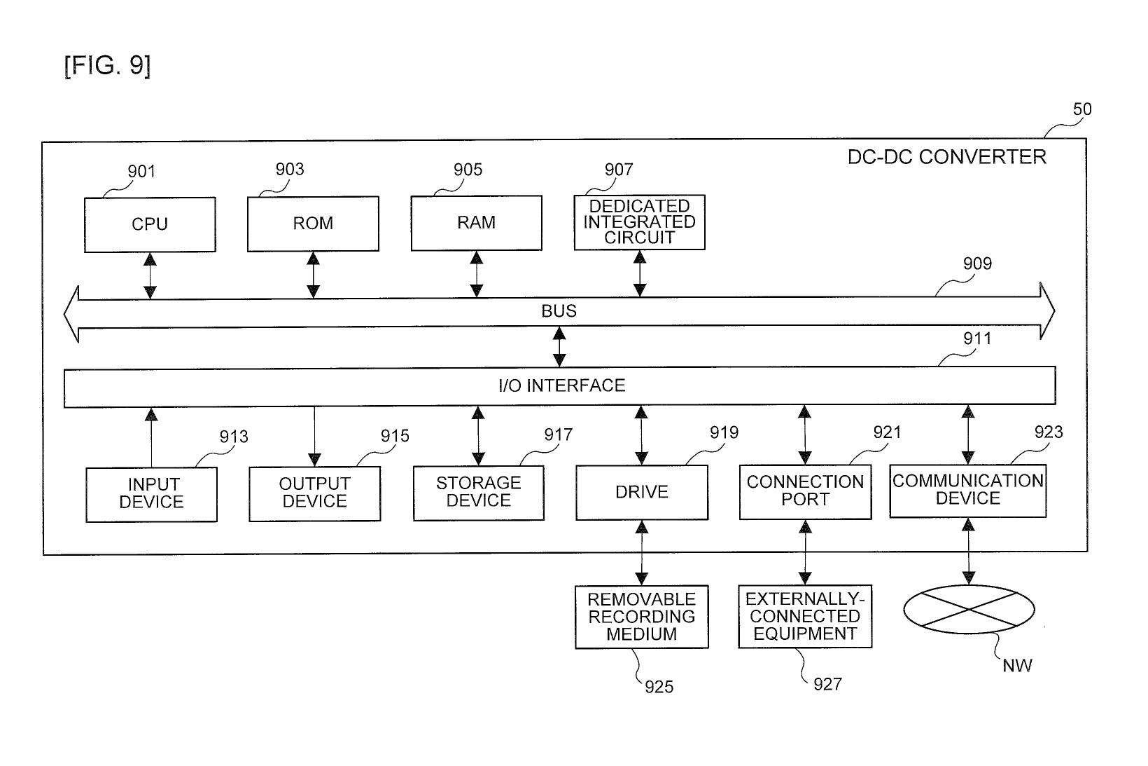

The control signal generation part 110 is implemented by a program executed by a CPU 901 of the DC-DC converter 50 (see FIG. 9 to be described later). The control signal generation part 110 performs at least one of superposition of a predetermined AC voltage on the second DC voltage and superposition of a predetermined AC current on the second DC current. That is, the control signal generation part 110 corresponds to an example of means for performing at least one of superposition of a predetermined AC voltage on the DC voltage in the second DC power and superposition of a predetermined AC current on the DC current in the second DC power.

In the embodiment, the control signal generation part 110 generates and outputs a control signal S for each of the semiconductor switches SW1-SW6 by a PWM control system. As a result, the control signal generation part 110 performs switching control (ON/OFF control) of the semiconductor switches SW1-SW6 so as to perform the power conversion operation (the charge/discharge operation of the power storage device 70) and performs at least one of superposition of an AC voltage on the second DC voltage and superposition of an AC current on the second DC current. Meanwhile, the control signal generation part 110 may perform at least one of the superposition of an AC voltage on the second DC voltage and the superposition of an AC current on the second DC current by generating and outputting a control signal by a system other than the PWM control system (such as a PFM control system).

On this occasion, the control signal generation part 110 generates and outputs the control signal S superposed with an AC instruction being a target AC value whose frequency changes within a predetermined frequency range to a DC instruction (hereinafter, it is also called a “second DC instruction”) being a target DC value on the second DC line Ld2 side (the power storage device 70 side). As a result, the control signal generation part 110 performs at least one of the superposition of an AC voltage whose frequency changes within a predetermined frequency range on the second DC voltage and the superposition of an AC current whose frequency changes within a predetermined frequency range on the second DC current. Meanwhile, the control signal generation part 110 may perform at least one of the superposition of an AC voltage on the second DC voltage and the superposition of an AC current on the second DC current by a method other than the method for generating and outputting the control signal S in which an AC instruction whose frequency changes within a predetermined frequency range has been superposed on the second DC instruction.

Here, as the charge/discharge system of the power storage device 70, various systems are available, and, in the embodiment, an instance that the charge/discharge system of the power storage device 70 is a system performing constant current charge/discharge and constant voltage charge/discharge in a switching manner at appropriate timing will be explained. However, the charge/discharge system of the power storage device 70 is not limited to the system performing constant current charge/discharge and constant voltage charge/discharge in a switching manner at appropriate timing, but may be another system. Further, in the embodiment, the control signal generation part 110 executes processes different from each other in an instance that the power storage device 70 is controlled so as to perform the constant current charge/discharge and in an instance that the power storage device 70 is controlled so as to perform the constant voltage charge/discharge.

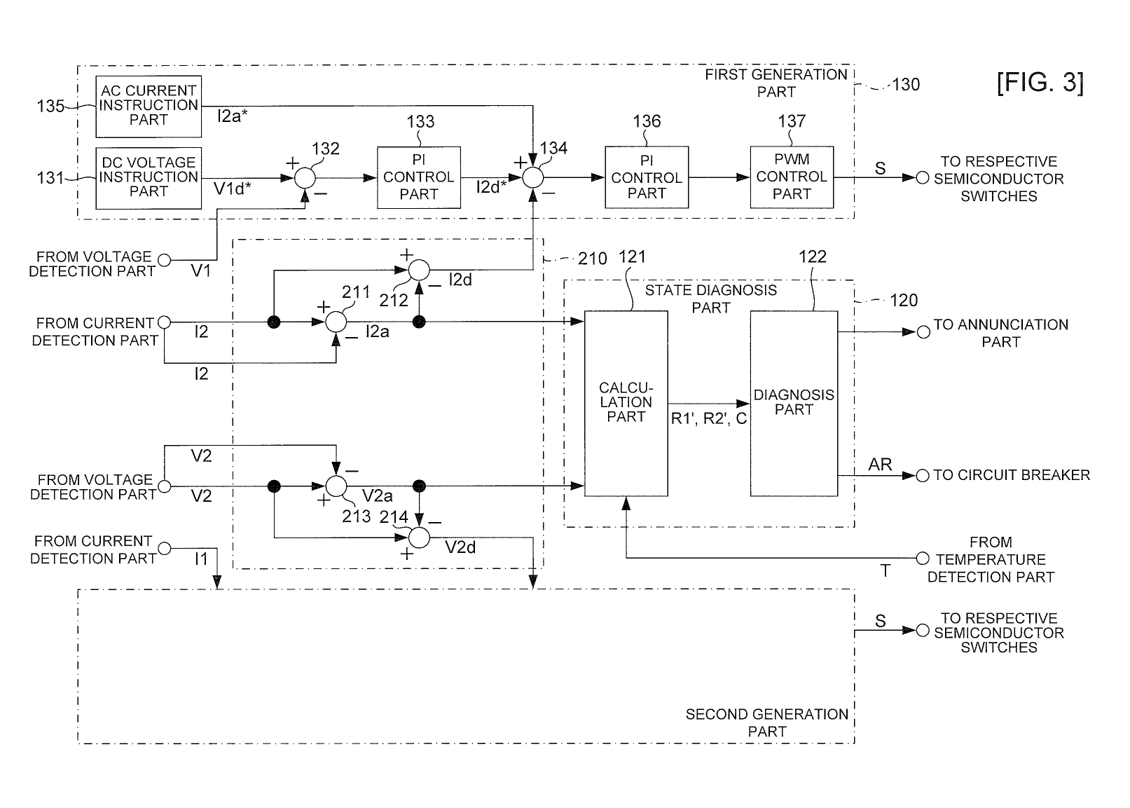

That is, when the power storage device 70 is controlled so as to perform the constant current charge/discharge, the control signal generation part 110 generates and outputs the control signal S in which an AC current instruction I2a* (see FIG. 3 etc. to be described later) being a target AC current value in the AC instruction has been superposed on a DC current instruction I2d* (see FIG. 3 etc. to be described later, hereinafter, it is also called a “second DC current instruction I2d*”) being a target DC current value in the second DC instruction. As a result, the control signal generation part 110 performs the superposition of the AC voltage on the second DC voltage and the superposition of the AC current on the second DC current.

On the other hand, when the power storage device 70 is controlled so as to perform the constant voltage charge/discharge, the control signal generation part 110 generates and outputs the control signal S in which an AC voltage instruction being a target AC voltage value in the AC instruction has been superposed on a DC voltage instruction (hereinafter, it is also called a “second DC voltage instruction”) being a target DC voltage value in the second DC instruction. As a result, the control signal generation part 110 performs the superposition of the AC voltage on the second DC voltage, and the superposition of the AC current on the second DC current.

Further, in the embodiment, the control signal generation part 110 has a first generation part 130 and a second generation part 140. Then, when the power storage device 70 is controlled so as to perform the constant current charge/discharge, the first generation part 130 performs, by generating and outputting the control signal S in which the AC current instruction I2a* is superposed on the second DC current instruction I2d*, the superposition of the AC voltage on the second DC voltage and the superposition of the AC current on the second DC current. On the other hand, when the power storage device 70 is controlled so as to perform the constant voltage charge/discharge, the second generation part 140 performs, by generating and outputting the control signal S in which the AC voltage instruction is superposed on the second DC voltage instruction, the superposition of the AC voltage on the second DC voltage and the superposition of the AC current of the second DC current. Meanwhile, processes etc. in the first generation part 130 and second generation part 140 of the control signal generation part 110 are not limited to the example of allotment of these processes, but, for example, they may be processed in one processing part or in three or more processing parts furthermore segmentalized.

Further, in the embodiment, an instance that the control signal generation part 110 is implemented by a program executed by the CPU 901 is explained, but, in the control signal generation part 110, a part or the whole thereof may be implemented with an actual device such as ASIC, FPGA or another electric circuit.

In the detection signal processing part 200, a part or the whole thereof is implemented with ASIC, FPGA, another electric circuit or the like. The detection signal processing part 200 detects at least one of the second DC voltage detection value V2 superposed with the AC voltage and the second DC current detection value I2 superposed with the AC current. That is, the detection signal processing part 200 corresponds to an example of means for detecting at least one of a detection value of a DC voltage superposed with an AC voltage and a detection value of a DC current superposed with an AC current.

In the embodiment, the detection signal processing part 200 has a voltage detection part 58, a current detection part 59, and an AC component detection part 210.

The voltage detection part 58 is connected to a middle of the other end of the reactor 543 and a terminal of the capacitor 544 on the second terminal 52a side, and to a terminal of the capacitor 544 on the second terminal 52b side. The voltage detection part 58 detects the voltage between the two connection points as a voltage at least including the second DC voltage, and outputs the same to the AC component detection part 210 as the second DC voltage detection value V2. Meanwhile, when an AC voltage is superposed on the second DC voltage according to the control signal S, the voltage detection part 58 detects a voltage in which an AC voltage is superposed on the second DC voltage, and outputs the same to the AC component detection part 210 as the second DC voltage detection value V2 superposed with an AC voltage.

The current detection part 59 is disposed between the second terminal 52b and a terminal of the capacitor 544 on the second terminal 52b side. The current detection part 59 detects the current at the setting place thereof as a current at least including the second DC current, and outputs the same to the AC component detection part 210 as the second DC current detection value I2. Meanwhile, when an AC current is superposed on the second DC current according to the control signal S, the current detection part 59 detects a current in which an AC current is superposed on the second DC current, and outputs the same to the AC component detection part 210 as the second DC current detection value I2 superposed with an AC current.

The AC component detection part 210 obtains the second DC voltage detection value V2 superposed with the AC voltage from the voltage detection part 58, and obtains the second DC current detection value I2 superposed with the AC current from the current detection part 59. Then, the AC component detection part 210 detects, based on the second DC voltage detection value V2 and the second DC current detection value I2, an AC voltage component value V2a (see FIG. 3 etc. to be described later) in the second DC voltage detection value V2 and an AC current component value I2a (see FIG. 3 etc. to be described later) in the second DC current detection value I2, and outputs these to the control part 100.

Meanwhile, processes etc. in the voltage detection part 58, the current detection part 59 and the AC component detection part 210 of the detection signal processing part 200 are not limited to the example of allotment of these processes, but, for example, they may be processed in one processing part or in four or more processing parts furthermore segmentalized. Further, in the embodiment, an instance that a part or the whole of the detection signal processing part 200 is implemented with an actual device such as ASIC, FPGA or another electric circuit is explained, but the detection signal processing part 200 may be implemented by a program executed by the CPU 901.

The state diagnosis part 120 is implemented by a program executed by the CPU 901. The state diagnosis part 120 diagnoses a state of the power storage device 70 based on at least one of the second DC voltage detection value V2 superposed with the AC voltage and the second DC current detection value I2 superposed with the AC current. That is, the state diagnosis part 120 corresponds to an example of means for diagnosing a state of a power storage device based on at least one of a detection value of a DC voltage and a detection value of a DC current. Meanwhile, in the embodiment, an instance that the state diagnosis part 120 is implemented by a program executed by the CPU 901 is explained, but, a part or whole of the state diagnosis part 120 may be implemented with an actual device such as ASIC, FPGA, or another electric circuit.

Next, while referring to FIGS. 3 to 7, an example of configuration of each of the first generation part 130 and the second generation part 140 of the control signal generation part 110, the AC component detection part 210 of the detection signal processing part 200, and the state diagnosis part 120 will be explained in detail.

### <Configuration Example of First Generation Part>

In FIG. 3, the first generation part 130 includes a DC voltage instruction part 131, an AC current instruction part 135, two subtractors 132, 134, two PI control parts 133, 136, and a PWM control part 137.

The DC voltage instruction part 131 outputs, when the power storage device 70 is controlled so as to perform the constant current charge/discharge, a DC voltage instruction V1d* (hereinafter, it is also called a “first DC voltage instruction V1d*”) being a target DC voltage value on the first DC line Ld1 side.

The subtractor 132 gets deflection of the first DC voltage instruction V1d* from the DC voltage instruction part 131 and the first DC voltage detection value V1 corresponding to the first DC voltage, from the voltage detection part 56, and sets the same as output.

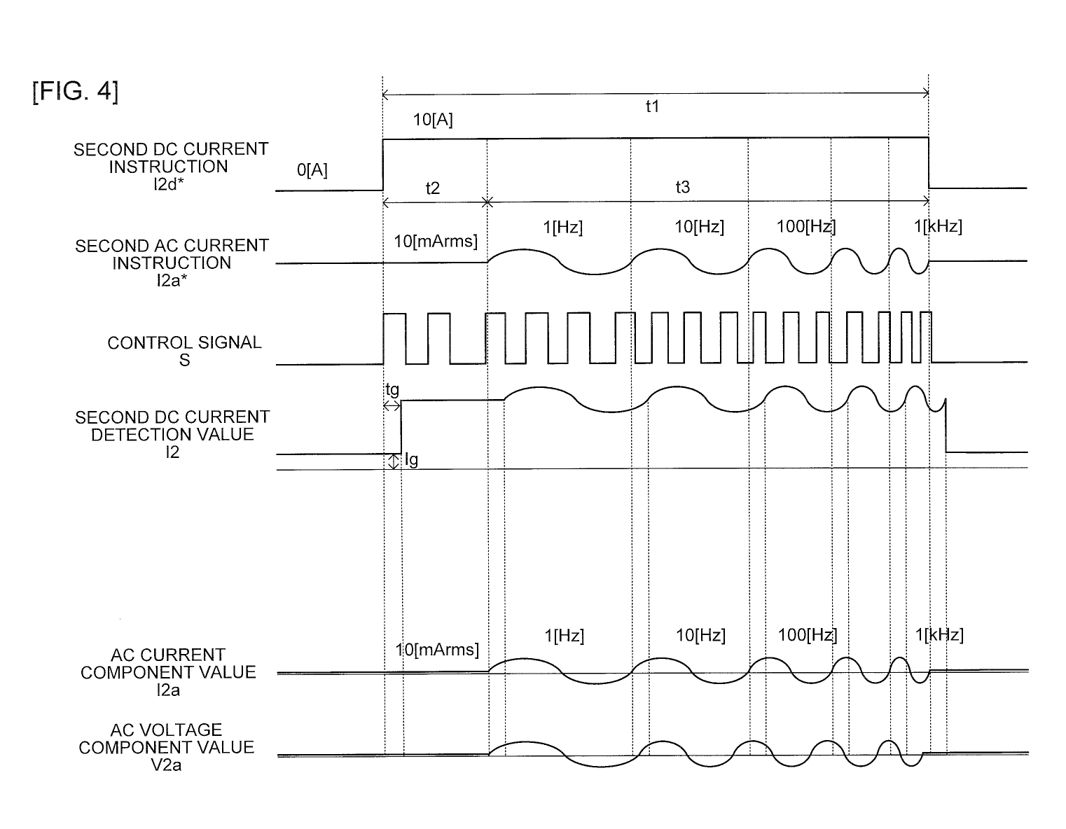

The PI control part 133 outputs the second DC current instruction I2d* by performing a known PI control on the output of the subtractor 132. On this occasion, the PI control part 133 outputs, as shown in FIG. 4, the second DC current instruction I2d* that becomes an approximately constant current value (in the shown example, 10 [A]) in a predetermined period t1.

The AC current instruction part 135 outputs, when the power storage device 70 is controlled so as to perform the constant current charge/discharge, the second AC current instruction I2a*. On this occasion, the AC current instruction part 135 outputs, as shown in FIG. 4, the second AC current instruction I2a* that is not an AC current in an initial period t2 in the period t1 and becomes, in a predetermined period t3 after the period t2, a predetermined effective value (in the shown example, 10 [mArms]) whose frequency changes within a predetermined frequency range (in the shown example, 1 [Hz]-1 [kHz]).

The subtractor 134 superposes the second AC current instruction I2a* from the AC current instruction part 135 on the second DC current instruction I2d* from the PI control part 133, and, at the same time, gets the deflection of the same and a DC current component value I2d to be described later from a subtractor 212 from the AC component detection part 210 to be described later, and sets the same as output.

A PI control part 136 performs a known PI control on the output of the subtractor 134 and sets the same as an output.

The PWM control part 137 generates and outputs the control signal S (see FIG. 4) for each of the semiconductor switches SW1-SW6 by performing the known PI control on the output of the PI control part 136. As a result, the semiconductor switches SW1-SW6 perform ON/OFF operation according to the control signal S, and a power conversion operation (charge/discharge operation of the power storage device 70) is performed. On this occasion, in the period corresponding to the period t2, the AC current is not superposed on the second DC current, but, in the period corresponding to the period t3, the AC current is superposed on the second DC current. In the same way, in the period corresponding to the period t2, the AC voltage is not superposed on the second DC voltage, but, in the period corresponding to the period t3, the AC voltage is superposed on the second DC voltage.

Accordingly, as shown in FIG. 4, in the period corresponding to the period t2, the second DC current detection value I2 of the current detection part 59 gives a detection value of the second DC current alone, because the AC current is not superposed on the second DC current. Further, in the period corresponding to the period t3, the second DC current detection value I2 of the current detection part 59 gives a detection value including the second DC current component and the AC current component, because the AC current is superposed on the second DC current. Meanwhile, the second DC current detection value I2 includes a current detection error Ig for the second DC current instruction I2d* and detection delay time tg for the second DC current instruction I2d*.

Further, although not shown in the drawing in particular, in the period corresponding to the period t2, the second DC voltage detection value V2 of the voltage detection part 58 is a detection value of the second DC voltage alone, because the AC voltage is not superposed on the second DC voltage. Furthermore, in the period corresponding to the period t3, the second DC voltage detection value V2 of the voltage detection part 58 becomes a detection value including the second DC voltage component and the AC voltage component, because the AC voltage is superposed on the second DC voltage.

Meanwhile, needless to say, the configuration of the first generation part 130 is not limited to the content, but may be another content.

### <Configuration Example of Second Generation Part>

Processing contents of the second generation part 140 become basically the same as contents obtained by replacing the wording “current” with “voltage” in the processing contents of the first generation part 130 explained above, and therefore the explanation thereof is omitted.

### <Configuration Example of AC Component Detection Part>

The AC component detection part 210 includes four subtractors 211, 212, 213, 214.

The subtractor 211 subtracts the second DC current detection value I2 (before the superposition of the AC current), which corresponds to the second DC current output from the current detection part 59, from the second DC current detection value I2 superposed with the AC current, output from the current detection part 59. As a result, the subtractor 211 corrects the current detection error Ig and the detection delay time tg, and, at the same time, calculates the AC current component value I2a in the second DC current detection value I2 superposed with the AC current (see FIG. 4), and outputs the same to the subtractor 212 and the state diagnosis part 120.

The subtractor 212 subtracts the AC current component value I2a output from the subtractor 211, from the second DC current detection value I2 superposed with the AC current, output from the current detection part 59. As a result, the subtractor 212 calculates the DC current component value I2d in the second DC current detection value I2 superposed with the AC current, and outputs the same to the subtractor 134 of the first generation part 130.

The subtractor 213 subtracts the second DC voltage detection value V2 (before the superposition of the AC voltage), which corresponds to the second DC voltage output from the voltage detection part 58, from the second DC voltage detection value V2 superposed with the AC voltage, output from the voltage detection part 58. As a result, the subtractor 213 corrects the voltage detection error and the detection delay time, and, at the same time, calculates the AC voltage component value V2a in the second DC voltage detection value V2 superposed with the AC voltage (see FIG. 4), and outputs the same to the subtractor 214 and the state diagnosis part 120.

The subtractor 214 subtracts the AC voltage component value V2a output from the subtractor 213, from the second DC voltage detection value V2 superposed with the AC voltage, output from the voltage detection part 58. As a result, the subtractor 214 calculates a DC voltage component value V2d in the second DC voltage detection value V2 superposed with the AC voltage, and outputs the same to the second generation part 140.

Meanwhile, needless to say, the configuration of the AC component detection part 210 is not limited to the content, but may be another content.

### <Configuration Example of State Diagnosis Part>

The state diagnosis part 120 diagnoses, as mentioned above, a state of the power storage device 70 based on at least one of the second DC voltage detection value V2 superposed with the AC voltage and the second DC current detection value I2 superposed with the AC current. On this occasion, the state diagnosis part 120 calculates a state quantity of the power storage device 70 by a known AC impedance method based on at least one (in the embodiment, both) of the AC current component value I2a and the AC voltage component value V2a, and, based on the state quantity, diagnoses a state of the power storage device 70. Meanwhile, the state diagnosis part 120 may diagnose a state of the power storage device 70 by a method other than the method for calculating a state quantity of the power storage device 70 by the AC impedance method based on at least one of the AC current component value I2a and the AC voltage component value V2a and diagnosing a state of the power storage device 70 based on the state quantity.

Here, as deterioration of the power storage device 70 progresses, a resistance value of the power storage device 70 increases and capacitance thereof decreases, and, therefore, by using at least one of the resistance value and the capacitance as an indicator, diagnosing the deterioration state of the power storage device 70 is possible. Further, when an abnormality (such as short circuit) occurs in the power storage device 70, a resistance value of the power storage device 70 decreases, and, therefore, by using the resistance value as an indicator, diagnosing an abnormality of the power storage device 70 is possible. Accordingly, when diagnosing a deterioration state of the power storage device 70, the state diagnosis part 120 may calculate at least one of the resistance value and capacitance of the power storage device 70 as the state quantity, and, based on at least one of the resistance value and capacitance, may diagnose the deterioration state of the power storage device 70. On the other hand, when diagnosing an abnormality of the power storage device 70, the state diagnosis part 120 may calculate a resistance value of the power storage device 70 as the state quantity, and, based on the resistance value, may diagnose the abnormality of the power storage device 70.

Meanwhile, when diagnosing a deterioration state of the power storage device 70, the state diagnosis part 120 may calculate at least one of the resistance value and capacitance of the power storage device 70, but, in the embodiment, an instance that the state diagnosis part 120 calculates both the resistance value and capacitance of the power storage device 70 will be explained. Further, states that the state diagnosis part 120 may diagnose are not limited to both a deterioration state and abnormality of the power storage device 70, but may be either one of a deterioration state and abnormality of the power storage device 70. Further, in an instance that the state diagnosis part 120 diagnoses both the deterioration state and abnormality of the power storage device 70, regarding the abnormality of the power storage device 70, real time diagnosis is suitable, but, regarding the deterioration state of the power storage device 70, real time diagnosis is unnecessary and diagnosis only at appropriate timing may be performed. However, in the embodiment, an instance that the state diagnosis part 120 diagnoses both the deterioration state and abnormality of the power storage device 70 in real time will be explained.

That is, the state diagnosis part 120 calculates a resistance value and capacitance of the power storage device 70 by the AC impedance method based on the AC current component value I2a and the AC voltage component value V2a. Then, the state diagnosis part 120 diagnoses a deterioration state of the power storage device 70 based on the resistance value and capacitance. Further, the state diagnosis part 120 diagnoses an abnormality of the power storage device 70 based on the resistance value.

In the embodiment, the state diagnosis part 120 includes a calculation part 121 and a diagnosis part 122.

The calculation part 121 calculates a resistance value and capacitance of the power storage device 70 by the AC impedance method based on the AC current component value I2a from the subtractor 211 and the AC voltage component value V2a from the subtractor 213. On this occasion, the calculation part 121 calculates known solution resistance and known charge-transfer resistance as a resistance value of the power storage device 70, and calculates a known electric double layer capacity as capacitance of the power storage device 70. Meanwhile, the resistance value of the power storage device 70 is not limited to the solution resistance and charge-transfer resistance, and the capacitance of the power storage device 70 is not limited to the electric double layer capacity.

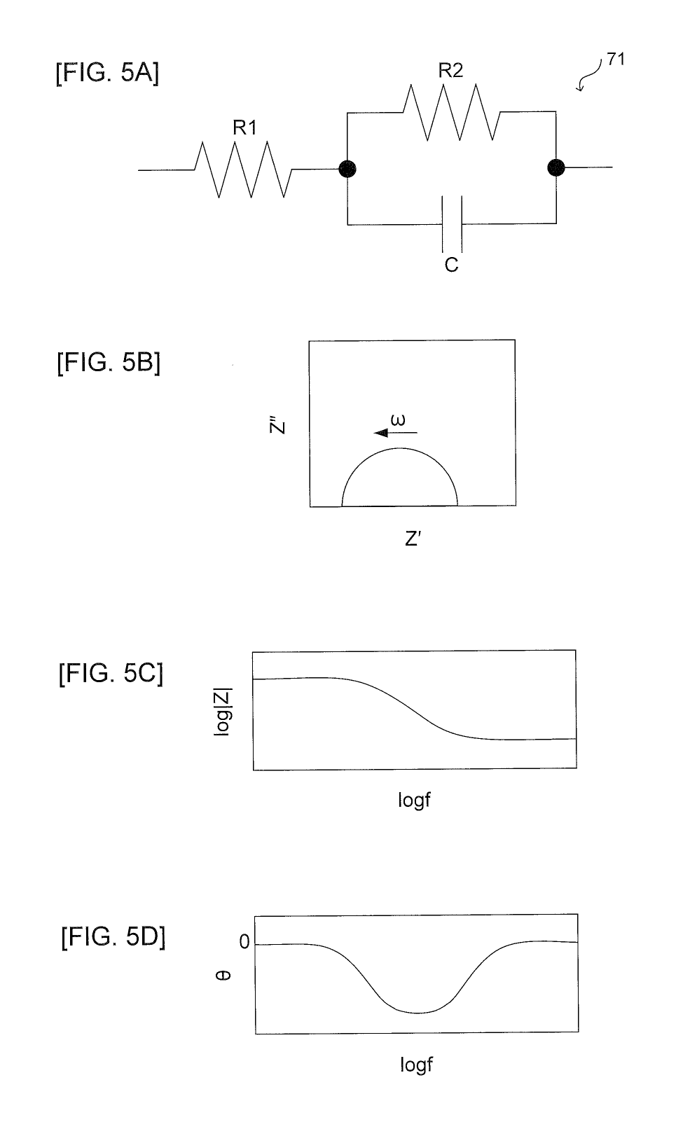

Here, in the embodiment that the power storage device 70 is a lithium ion secondary battery, an equivalent circuit of the power storage device 70 is an equivalent circuit 71 as shown in FIG. 5A. That is, as shown in FIG. 5A, the equivalent circuit 71 of the power storage device 70 includes a solution resistance R1 and a charge-transfer resistance R2 and an electric double layer capacity C connected in parallel. Meanwhile, FIG. 5B shows a plot (also called a “Nyquist plot” or a “complex plane plot”), in which, in a complex plane, a real number component Z′ of an AC impedance of the equivalent circuit 71 is represented on the abscissa axis and an imaginary number component Z″ is represented on the ordinate axis. Further, FIG. 5C shows a plot (also called a “Bode plot”), in which the logarithm of frequency f is represented on the abscissa axis and the logarithm of an absolute value |Z| of AC impedance in the equivalent circuit 71 is represented on the ordinate axis. FIG. 5D shows a plot (also called a “Bode plot”), in which the logarithm of the frequency f is represented on the abscissa axis and phase difference θ of the AC impedance in the equivalent circuit 71 is represented on the ordinate axis.

Further, AC impedance Z of the equivalent circuit 71 may be calculated by a formula (1) below.

$$Z = R 1 + \frac{R 2}{1 + jω R 2 C} \qquad formula ( 1 )$$

In the formula (1), Z is AC impedance [Ω], R1 is solution resistance [Ω], R2 is charge-transfer resistance [Ω], C is electric double layer capacity [F], and ω is 2πf (f is frequency [Hz]).

A division of the formula (1) into a real number part and an imaginary number part gives formulae (2)-(4) below.

$$\begin{matrix}Z = {Z}^{′} - j {Z}^{″} & formula ( 2 ) \\ {Z}^{′} = R 1 + \frac{R 2}{1 + {ω}^{2} R {2}^{2} {C}^{2}} & formula ( 3 ) \\ {Z}^{″} = \frac{ω R {2}^{2} C}{1 + {ω}^{2} R {2}^{2} {C}^{2}} & formula ( 4 )\end{matrix}$$

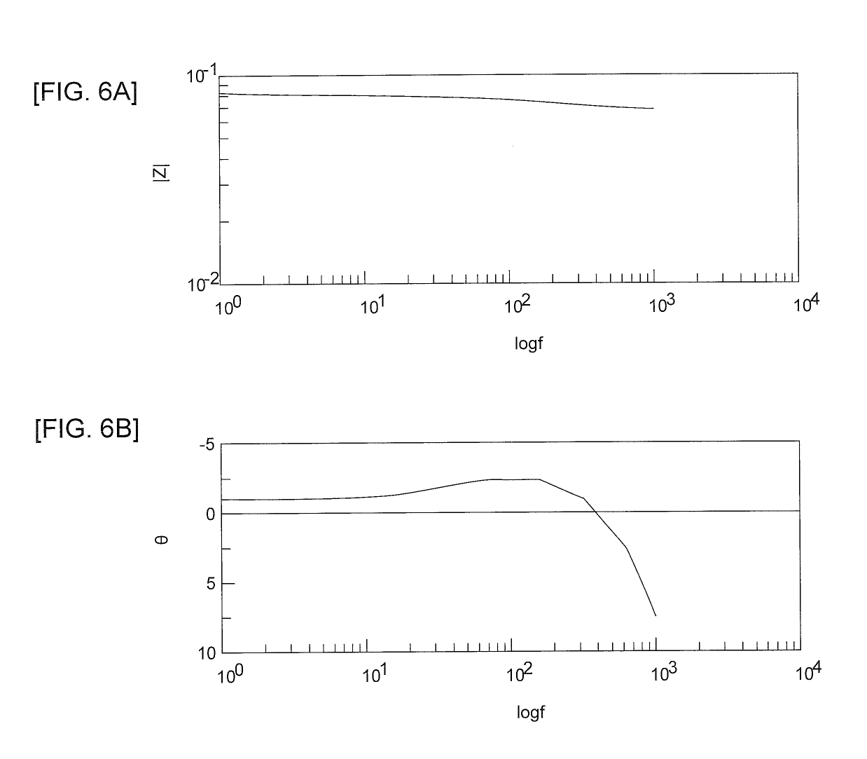

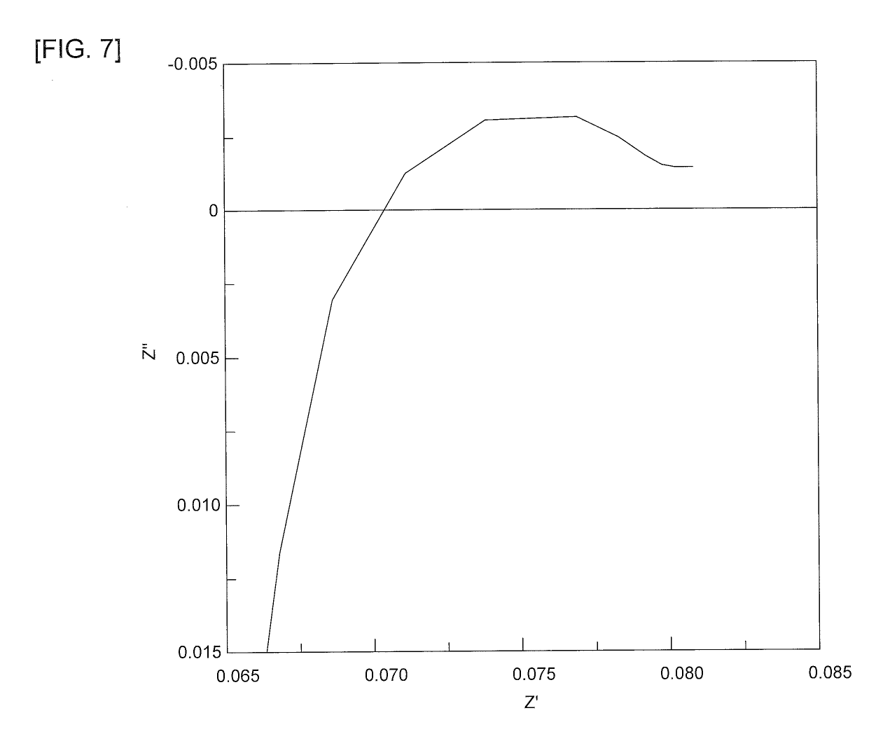

The calculation part 121 derives a Bode plot (see, for example, FIGS. 6A, 6B) or a Nyquist plot (see, for example, FIG. 7) related to the power storage device 70 using the formula (1) or the formulae (3), (4). Then, based on the Bode plot or the Nyquist plot, the calculation part 121 derives the solution resistance R1, the charge-transfer resistance R2 and the electric double layer capacity C of the power storage device 70. Meanwhile, the derivation method of the solution resistance R1, the charge-transfer resistance R2 and the electric double layer capacity C here is known, and, therefore, a concrete explanation thereof is omitted.

Here, the values of the solution resistance R1 and the charge-transfer resistance R2 change according to temperature of the power storage device 70. Consequently, in the embodiment, the calculation part 121 obtains detection temperature T from the temperature detection part 80, and, using the detection temperature T, corrects the solution resistance R1 and the charge-transfer resistance R2. Concretely, the calculation part 121 corrects the solution resistance R1 and the charge-transfer resistance R2 by formulae (5), (6) below that use the detection temperature T.

R1′=(234.5+20)/(234.5+T)R1 formula (5)

R2′=(234.5+20)/(234.5+T)R2 formula (6)

Meanwhile, in the formulae (5), (6), R1′ is the solution resistance R1 after the correction, and R2′ is the charge-transfer resistance R2 after the correction.

Meanwhile, the calculation part 121 may merely correct the solution resistance R1 and the charge-transfer resistance R2 using the detection temperature T, and it is not limited to the instance of correcting the solution resistance R1 and the charge-transfer resistance R2 according to the formulae (5), (6). Further, the calculation part 121 does not necessarily correct the solution resistance R1 and the charge-transfer resistance R2 using the detection temperature T.

Then, the calculation part 121 outputs the solution resistance R1′, the charge-transfer resistance R2′, and the electric double layer capacity C to the diagnosis part 122.

Meanwhile, needless to say, the function of the calculation part 121 is not limited to the content, but may be another content.

The diagnosis part 122 diagnoses a state of the power storage device 70 based on the solution resistance R1′, the charge-transfer resistance R2′, and the electric double layer capacity C, from the calculation part 121.

That is, the diagnosis part 122 diagnoses a deterioration state of the power storage device 70 based on the solution resistance R1′, the charge-transfer resistance R2′, and the electric double layer capacity C, from the calculation part 121. For example, the diagnosis part 122 may diagnose, as a deterioration state of the power storage device 70, a deterioration degree (how much it deteriorates) of the power storage device 70, or may diagnose whether or not the power storage device 70 has reached a previously set deterioration state. However, in the embodiment, an instance that the diagnosis part 122 diagnoses whether or not the power storage device 70 has reached a previously set deterioration state will be explained.

On this occasion, the diagnosis part 122 compares the solution resistance R1′, the charge-transfer resistance R2′ and the electric double layer capacity C, respectively, with initial values thereof recorded at such as first start-up of the power storage device 70, and diagnoses according to these comparison results whether or not the power storage device 70 has been in a previously set deterioration state. More concretely, the diagnosis part 122 compares the solution resistance R1′ with an initial value R1₀ of the solution resistance, compares the charge-transfer resistance R2′ with an initial value R2₀ of the charge-transfer resistance, and compares the electric double layer capacity C with an initial value C₀ of the electric double layer capacity. Then, the diagnosis part 122 diagnoses that the power storage device 70 has become a previously set deterioration state when the solution resistance R1′ becomes twice as large as the initial value R1₀, or the charge-transfer resistance R2′ becomes twice as large as the initial value R2₀, or the electric double layer capacity C becomes 0.4 times as large as the initial value C₀. Meanwhile, multiplication factors relative to the initial values R1₀, R2₀, C₀ for diagnosing that the power storage device 70 has become a previously set deterioration state are different depending on specifications of the power storage device 70 etc., and the numerical values are merely an example. Further, the diagnosis part 122 may diagnose whether or not the power storage device 70 has become a previously set deterioration state by comparison with previously set threshold values instead of the comparison with initial values R1₀, R2₀, C₀.

Further, the diagnosis part 122 diagnoses abnormalities of the power storage device 70 (for example, if it is in a short circuit state or in a state just before a short circuit state) based on the solution resistance R1′ and the charge-transfer resistance R2′ from the calculation part 121. For example, the diagnosis part 122 may diagnose as an abnormality of the power storage device 70 in an instance that the solution resistance R1′ or the charge-transfer resistance R2′ becomes less than or equal to a previously set threshold value. Alternatively, the diagnosis part 122 may diagnose as an abnormality of the power storage device 70 in an instance that a decreasing degree of a present solution resistance R1′ or charge-transfer resistance R2′ relative to a past solution resistance R1′ or charge-transfer resistance R2′ has become more than or equal to a previously set threshold value. In the embodiment, however, an instance that the diagnosis part 122 diagnoses as an abnormality of the power storage device 70 when the solution resistance R1′ or the charge-transfer resistance R2′ has become less than or equal to a previously set threshold value, will be explained.

Further, in the embodiment, in an instance that the diagnosis part 122 has diagnosed as an abnormality of the power storage device 70 as described above, it outputs an abnormality diagnosis signal AR (see FIG. 2 etc.) showing the purport to the circuit breaker 60. As a result, it is possible to cause the circuit breaker 60 to perform a breaking operation, and to break and disconnect the connection of the DC-DC converter 50 with the power storage device 70. Meanwhile, the diagnosis part 122, when having diagnosed as an abnormality of the power storage device 70, does not necessarily output the abnormality diagnosis signal AR to the circuit breaker 60, but may output it to another configuration instead of the circuit breaker 60 and cause the other configuration to perform an operation according to the abnormality diagnosis signal AR. Furthermore, the diagnosis part 122, when having diagnosed as an abnormality of the power storage device 70, does not necessarily output the abnormality diagnosis signal AR. In addition, the circuit breaker 60 may perform the breaking operation according to a signal from another configuration instead of the abnormality diagnosis signal AR from the diagnosis part 122.

Further, in the embodiment, the diagnosis part 122, when having diagnosed a deterioration state or abnormality of the power storage device 70 as described above, outputs an annunciation signal for performing annunciation based on the diagnosis result (for example, annunciation that the power storage device 70 has become a previously set deterioration state, annunciation that an abnormality has occurred in the power storage device 70, etc.) to the annunciation part 90. As a result, it is possible to cause the annunciation part 90 to perform an annunciation operation and to announce the diagnosis result of the diagnosis part 122 to a user etc. Meanwhile, the diagnosis part 122, when having diagnosed a deterioration state or abnormality of the power storage device 70, does not necessarily output the annunciation signal. In an instance that the diagnosis part 122 does not output the annunciation signal, the annunciation part 90 may be omitted.

Meanwhile, needless to say, the function of the diagnosis part 122 is not limited to the content, but may be another content.

Further, processes etc. in the calculation part 121 and the diagnosis part 122 of the state diagnosis part 120 are not limited to examples of apportionment of these processes, but, for example, they may be processed by one processing part or may be processed by further segmentalized three or more processing parts.

### <Method for Diagnosing State of Power Storage Device>

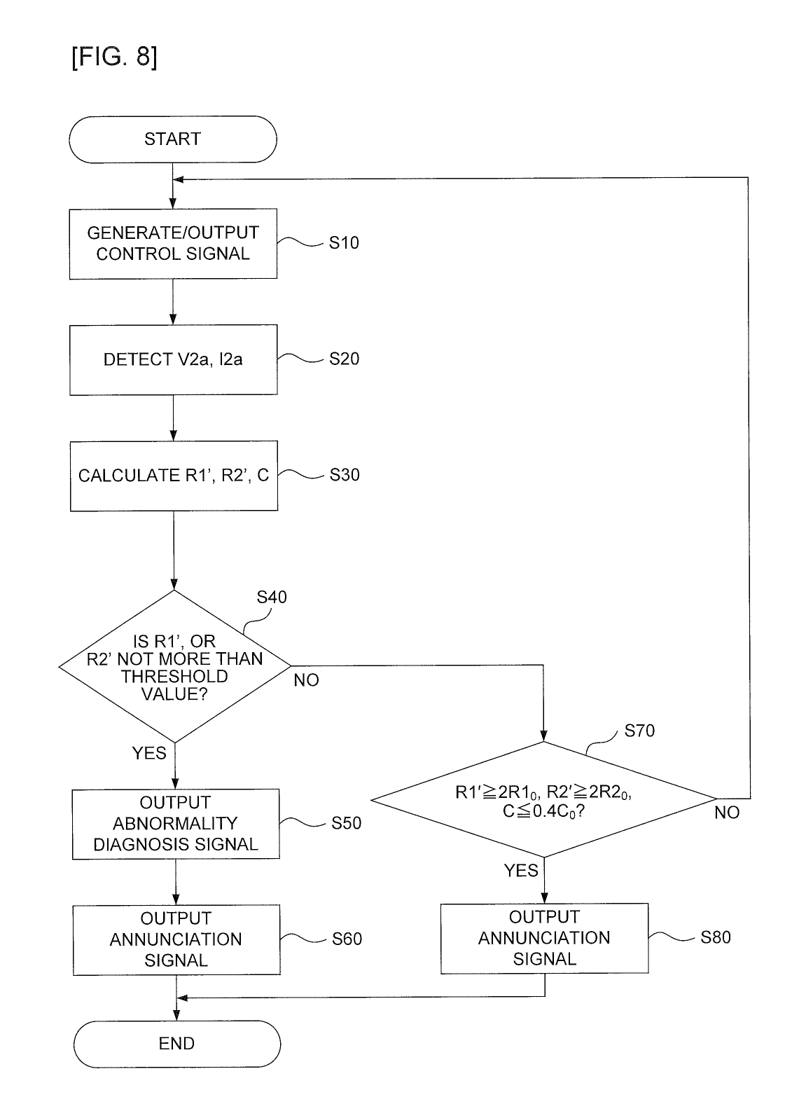

Next, while referring to FIG. 8, one example of a control procedure by a method for diagnosing a state of the power storage device 70 executed by the DC-DC converter 50 will be explained.

As shown in FIG. 8, first, at step S10, the DC-DC converter 50 generates and outputs the control signal S, in which an AC instruction whose frequency changes within a predetermined frequency range is superposed on the second DC instruction, in the control signal generation part 110. Concretely, when the control is performed so that the power storage device 70 performs constant current charge/discharge, it generates and outputs the control signal S, in which the AC current instruction I2a* is superposed on the second DC current instruction I2d*, in the control signal generation part 110. On the other hand, when the control is performed so that the power storage device 70 performs constant voltage charge/discharge, it generates and outputs the control signal S, in which the AC voltage instruction is superposed on the second DC voltage instruction, in the control signal generation part 110. Hereby, in the control signal generation part 110, the superposition of an AC voltage whose frequency changes within a predetermined frequency range on the second DC voltage is performed, and the superposition of an AC current whose frequency changes within a predetermined frequency range on the second DC current is performed.

Then, at step S20, the DC-DC converter 50 detects, in the detection signal processing part 200, the AC voltage component value V2a in the second DC voltage detection value V2 superposed with the AC voltage according to the control signal S output at the step S10, and the AC current component value I2a in the second DC current detection value I2 superposed with the AC current according to the control signal S.

Then, at step S30, the DC-DC converter 50 calculates the solution resistance R1′, the charge-transfer resistance R2′, and the electric double layer capacity C by the AC impedance method based on the AC voltage component value V2a and the AC current component value I2a detected at the step S20, in the calculation part 121 of the state diagnosis part 120.

Then, at step S40, the DC-DC converter 50 diagnoses an abnormality of the power storage device 70 by determining whether or not the solution resistance R1′ or the charge-transfer resistance R2′ calculated at the step S30 has become less than or equal to a threshold value, in the diagnosis part 122 of the state diagnosis part 120. When the solution resistance R1′ or the charge-transfer resistance R2′ has become less than or equal to a threshold value, the state diagnosis part 120 diagnoses as an abnormality of the power storage device 70 and the determination at the step S40 is satisfied, and the procedure moves to step S50.

At the step S50, the DC-DC converter 50 outputs the abnormality diagnosis signal AR to the circuit breaker 60, in the diagnosis part 122 of the state diagnosis part 120. As a result, it is possible to cause the circuit breaker 60 to perform a breaking operation and to break and disconnect the connection of the DC-DC converter 50 with the power storage device 70.

Then, at step S60, the DC-DC converter 50 outputs an annunciation signal corresponding to the diagnosis result to the annunciation part 90, in the diagnosis part 122 of the state diagnosis part 120. As a result, it is possible to cause the annunciation part 90 to perform an annunciation operation, and to announce the diagnosis result of the diagnosis part 122 to a user etc. Subsequently, the process shown in the flow is terminated.

On the other hand, at the step S40, when each of the solution resistance R1′ and the charge-transfer resistance R2′ has not become a threshold value or less, the determination at the step S40 is not satisfied, and the procedure moves to step S70.

In the step S70, the DC-DC converter 50 diagnoses a deterioration state of the power storage device 70 by determining whether or not the solution resistance R1′ has become twice as large as the initial value R1₀, or the charge-transfer resistance R2′ has become twice as large as the initial value R2₀, or the electric double layer capacity C has become 0.4 times as large as the initial value C₀, in the diagnosis part 122 of the state diagnosis part 120. In an instance that the solution resistance R1′ has not become twice as large as the initial value R1₀, and that the charge-transfer resistance R2′ has not become twice as large as the initial value R2₀, and that the electric double layer capacity C has not become 0.4 times as large as the initial value C₀, the determination at the step S70 is not satisfied, and the procedure returns to the step S10, and the same procedure is repeated. On the other hand, in an instance that the solution resistance R1′ has become twice as large as the initial value R1₀, or that the charge-transfer resistance R2′ has become twice as large as the initial value R2₀, or that the electric double layer capacity C has become 0.4 times as large as the initial value C₀, the state diagnosis part 120 diagnoses that the power storage device 70 has become a previously set deterioration state. Thus, the determination at the step S70 is satisfied, and the procedure moves to step S80.

At the step S80, the DC-DC converter 50 outputs an annunciation signal corresponding to the diagnosis result to the annunciation part 90, in the diagnosis part 122 of the state diagnosis part 120. As a result, it is possible to cause the annunciation part 90 to perform an annunciation operation, and to announce the diagnosis result of the diagnosis part 122 to a user etc. Subsequently, the process shown in the flow is terminated.

### <Configuration Example of DC-DC Converter 50>

A configuration example will be described for the DC-DC converter 50 achieving the processes of the control signal generation part 110, the state diagnosis part 120, etc. implemented by a program executed by the CPU 901 described above, with reference to FIG. 9. In FIG. 9, a configuration related to a function of converting an electric power of the DC-DC converter 50 is not shown.

As shown in FIG. 9, the DC-DC converter 50 has, for example, a CPU 901, a ROM 903, a RAM 905, a dedicated integrated circuit 907 constructed for specific use such as an ASIC or an FPGA, an input device 913, an output device 915, a storage device 917, a drive 919, a connection port 921, and a communication device 923. These constituent elements are mutually connected via a bus 909 and an I/O interface 911 such that signals can be transferred.

The program can be recorded in a storage device such as the ROM 903, the RAM 905, and the storage device 917, for example.

The program can also temporarily or permanently be recorded in a removable recording medium 925 such as various optical disks including CDs, MO disks, and DVDs, and semiconductor memories. The removable recording medium 925 as described above can be provided as so-called packaged software. In this case, the program recorded in the removable recording medium 925 may be read by the drive 919 and recorded in the storage device 917 through the I/O interface 911, the bus 909, etc.

The program may be recorded in, for example, a download site, another computer, or another recording medium (not shown). In this case, the program is transferred through a network NW such as a LAN and the Internet and the communication device 923 receives this program. The program received by the communication device 923 may be recorded in the storage device 917 through the I/O interface 911, the bus 909, etc.

The program may be recorded in appropriate externally-connected equipment 927, for example. In this case, the program may be transferred through the appropriate connection port 921 and recorded in the storage device 917 through the I/O interface 911, the bus 909, etc.

The CPU 901 executes various process in accordance with the program recorded in the storage device 917 to implement the processes of the control signal generation part 110, the state diagnosis part 120, etc. In this case, the CPU 901 may directly read and execute the program from the storage device 917 or may be execute the program once loaded in the RAM 905. In the case that the CPU 901 receives the program through, for example, the communication device 923, the drive 919, or the connection port 921, the CPU 901 may directly execute the received program without recording in the storage device 917.

The CPU 901 may execute various processes based on a signal or information input from the input device 913 such as a mouse, a keyboard, and a microphone (not shown) as needed.

The CPU 901 may output a result of execution of the process from the output device 915 such as a display device and a sound output device, for example, and the CPU 901 may transmit this process result to the communication device 923 or the connection port 921 as needed or may record the process result into the storage device 917 or the removable recording medium 925.

### One Example of Effect According to the Embodiment

As described above, in the power conversion system 1 of the embodiment, the DC-DC converter 50 has the control signal generation part 110, the detection signal processing part 200, and the state diagnosis part 120. The control signal generation part 110 performs at least one of the superposition of a predetermined AC voltage on the second DC voltage and the superposition of a predetermined AC current on the second DC current. The detection signal processing part 200 detects at least one of the second DC voltage detection value V2 superposed with the AC voltage and the second DC current detection value I2 superposed with the AC current. The state diagnosis part 120 diagnoses a state of the power storage device 70 based on at least one of the second DC voltage detection value V2 and the second DC current detection value I2.

As described above, in the embodiment, the DC-DC converter 50 supplying the second DC power to the power storage device 70 diagnoses a state of the power storage device 70, and, therefore, disposition of an independent device for diagnosing a state of the power storage device 70 is unnecessary, and the system configuration can be made simple. Further, calculation of a state quantity of the power storage device 70 by the AC impedance method can be made possible, by detecting at least one of the AC voltage component value V2a in the second DC voltage detection value V2 and the AC current component value I2a in the second DC current detection value I2. In addition, by using the state quantity as an indicator, performing the state diagnosis of the power storage device 70 becomes possible. Accordingly, performing the state diagnosis of the power storage device 70 in real time in an ordinary operation of the DC-DC converter 50 becomes possible, and, therefore, lowering of the operating ratio of the power conversion system 1 can be prevented and it can be used for both deterioration state diagnosis and abnormality diagnosis of the power storage device 70. Consequently, convenience of the state diagnosis of the power storage device 70 can be improved.

Further, in the embodiment in particular, the control signal generation part 110 generates and outputs the control signal S in which an AC instruction whose frequency changes within a predetermined frequency range is superposed on the second DC instruction. As a result, at least one of the superposition of an AC voltage whose frequency changes within a predetermined frequency range on the second DC voltage and the superposition of a predetermined AC current whose frequency changes within a predetermined frequency range on the second DC current can be performed. Consequently, an alternate current whose frequency changes can be applied to the power storage device 70, and detection of at least one of the AC voltage component value V2a in the DC voltage detection value V2 and the AC current component value I2a in the DC current detection value I2, which change corresponding to a state of the power storage device 70, becomes possible. Further, the state diagnosis part 120 calculates a state quantity of the power storage device 70 by the AC impedance method based on at least one of the AC voltage component value V2a and the AC current component value I2a. As a result, by using the state quantity as an indicator, the state diagnosis of the power storage device 70 can be performed.

Further, in the embodiment in particular, the control signal generation part 110 generates and outputs, when the power storage device 70 is controlled so as to perform constant voltage charge/discharge, the control signal S in which an AC voltage instruction is superposed on the second DC voltage instruction, and generates and outputs, when the power storage device 70 is controlled so as to perform constant current charge/discharge, the control signal S in which the AC current instruction I2a* is superposed on the DC current instruction I2d*. As a result, in both in stances of the constant voltage charge/discharge and the constant current charge/discharge, at least one of the AC voltage component value V2a and the AC current component value I2a can be detected, and, therefore, possibility of state diagnosis of the power storage device 70 can be enhanced.

Further, in the embodiment in particular, the state diagnosis part 120 calculates at least one of a resistance value and capacitance of the power storage device 70, and, based on at least one of the resistance value and capacitance, diagnoses a deterioration state of the power storage device 70. As a result, by using at least one of the resistance value and capacitance as an indicator, the DC-DC converter 50 capable of diagnosing a deterioration state of the power storage device 70 can be realized.

Further, in the embodiment in particular, the state diagnosis part 120 diagnoses an abnormality of the power storage device 70 based on a resistance value of the power storage device 70. As a result, by using the resistance value as an indicator, the DC-DC converter 50 capable of performing an abnormality diagnosis of the power storage device 70 in real time in an ordinary operation can be realized. Consequently, it becomes possible to prevent or suppress to the minimum smoking/firing etc. of the power storage device 70.

Further, in the embodiment in particular, the circuit breaker 60 is disposed on the second DC line Ld2 between the DC-DC converter 50 and the power storage device 70, and the state diagnosis part 120 outputs the abnormality diagnosis signal AR, when it diagnoses as an abnormality of the power storage device 70. As a result, by causing the circuit breaker 60 to perform a breaking operation according to the abnormality diagnosis signal AR from the state diagnosis part 120, in a moment after diagnosis as an abnormality of the power storage device 70, the connection of the DC-DC converter 50 with the power storage device 70 can be disconnected, and the power conversion system 1 with high safety can be realized.

Further, in the embodiment in particular, the temperature detection part 80 detecting temperature of the power storage device 70 is disposed, and the state diagnosis part 120 corrects a resistance value of the power storage device 70 using the detection temperature T of the temperature detection part 80. As a result, a deterioration state and abnormality of the power storage device 70 can be diagnosed using a resistance value after the correction as an indicator, and, therefore, accuracy of the state diagnosis of the power storage device 70 can be improved and reliability can be improved.

Further, in the embodiment in particular, the annunciation part 90 performing annunciation based on a diagnosis result of the state diagnosis part 120 is disposed. As a result, for example, a deterioration degree, notice of exchange timing, abnormality etc. of the power storage device 70 can be announced to a user, and convenience can be improved.

### Modification Examples Etc

Meanwhile, embodiments are not limited to the contents, but various modifications are possible within a range that does not deviate from the gist and technical idea thereof.

Arrows shown in FIGS. 1 and 2 show an example of flow of a signal, and do not limit a flow direction of a signal.

The flow chart shown in FIG. 8 does not limit the content of the embodiment to the illustrated procedure, and, within a range that does not deviate from the gist and technical idea, addition or deletion, change of order etc. may be performed.

In addition, techniques by the embodiment etc. may be appropriately combined and utilized in addition to the examples having already described above.

In addition to that, although exemplification is not performed one by one, the embodiment etc. are carried out by various changes being applied thereto without departing from the technical idea of the present disclosure.

What is claimed is:

1. A power conversion system comprising:
a first power converter configured to convert AC power from an AC power source to first DC power;
a second power converter configured to convert the first DC power from the first power converter to another second DC power having a different power value from the first DC power; and
a power storage device configured to store the second DC power from the second power converter,
the second power converter comprising:
a control signal generation part configured to perform at least one of superposition of a predetermined AC voltage on a DC voltage in the second DC power and superposition of a predetermined AC current on a DC current in the second DC power;
a detection signal processing part configured to detect at least one of a detection value of the DC voltage superposed with the AC voltage and a detection value of the DC current superposed with the AC current; and
a state diagnosis part configured to diagnose a state of the power storage device based on at least one of the detection value of the DC voltage and the detection value of the DC current.

2. The power conversion system according to claim 1,
wherein the control signal generation part is configured to generate and output a control signal in which an AC instruction whose frequency changes within a predetermined frequency range is superposed on a DC instruction on a side of the power storage device, and
wherein the state diagnosis part is configured to calculate a state quantity of the power storage device by an AC impedance method based on at least one of an AC voltage component value in the detection value of the DC voltage and an AC current component value in the detection value of the DC current.

3. The power conversion system according to claim 2,
wherein the control signal generation part is
configured to generate and output the control signal in which an AC voltage instruction in the AC instruction is superposed on a DC voltage instruction in the DC instruction when the power storage device is controlled so as to perform charge and discharge with constant voltage, and
configured to generate and output the control signal in which an AC current instruction in the AC instruction is superposed on a DC current instruction in the DC instruction when the power storage device is controlled so as to perform charge and discharge with constant current.

4. The power conversion system according to claim 3,
wherein the state diagnosis part is
configured to calculate at least one of a resistance value and capacitance of the power storage device as the state quantity, and
configured to diagnose a deterioration state of the power storage device based on at least one of the resistance value and the capacitance.

5. The power conversion system according to claim 4,
wherein the state diagnosis part is configured to diagnose an abnormality of the power storage device based on the resistance value.

6. The power conversion system according to claim 5,
wherein the state diagnosis part is configured to output an abnormality diagnosis signal when the state diagnosis part diagnoses as the abnormality.

7. The power conversion system according to claim 6, further comprising
a circuit breaker disposed on a DC line between the second power converter and the power storage device, the circuit breaker being configured to perform a breaking operation according to the abnormality diagnosis signal from the state diagnosis part.

8. The power conversion system according to claim 7, further comprising
a temperature detection part configured to detect temperature of the power storage device,
wherein the state diagnosis part is configured to correct the resistance value using a detection temperature of the temperature detection part.

9. The power conversion system according to claim 8, further comprising
an annunciation part configured to annunciate based on a diagnosis result of the state diagnosis part.

10. A power converter configured to convert supplied first DC power to another second DC power having a different power value from the first DC power and to output the second DC power to a power storage device, comprising:
a control signal generation part configured to generate and output a control signal in which an AC instruction whose frequency changes within a predetermined frequency range is superposed on a DC instruction on a side of the power storage device to perform at least one of superposition of an AC voltage whose frequency changes within the predetermined frequency range on a DC voltage in the second DC power and superposition of an AC current whose frequency changes within the predetermined frequency range on a DC current in the second DC power;
a detection signal processing part configured to detect at least one of a detection value of the DC voltage superposed with the AC voltage and a detection value of the DC current superposed with the AC current; and
a state diagnosis part configured to calculate a state quantity of the power storage device by an AC impedance method based on at least one of an AC voltage component value in the detection value of the DC voltage and an AC current component value in the detection value of the DC current, and to diagnose a state of the power storage device based on the state quantity.

11. A method for diagnosing a state of a power storage device configured to store supplied second DC power, comprising:
generating and outputting a control signal in which an AC instruction whose frequency changes within a predetermined frequency range is superposed on a DC instruction on a side of the power storage device to perform at least one of superposition of an AC voltage whose frequency changes within the predetermined frequency range on a DC voltage in the second DC power and superposition of an AC current whose frequency changes within the predetermined frequency range on a DC current in the second DC power;
calculating a state quantity of the power storage device by an AC impedance method based on at least one of an AC voltage component value in a detection value of the DC voltage superposed with the AC voltage and an AC current component value in a detection value of the DC current superposed with the AC current; and
diagnosing the state of the power storage device based on the state quantity.

12. The power conversion system according to claim 2,
wherein the state diagnosis part is
configured to calculate at least one of a resistance value and capacitance of the power storage device as the state quantity, and
configured to diagnose a deterioration state of the power storage device based on at least one of the resistance value and the capacitance.

13. The power conversion system according to claim 12,
wherein the state diagnosis part is configured to diagnose an abnormality of the power storage device based on the resistance value.

14. The power conversion system according to claim 13,
wherein the state diagnosis part is configured to output an abnormality diagnosis signal when the state diagnosis part diagnoses as the abnormality.

15. The power conversion system according to claim 14, further comprising
a circuit breaker disposed on a DC line between the second power converter and the power storage device, the circuit breaker being configured to perform a breaking operation according to the abnormality diagnosis signal from the state diagnosis part.

16. The power conversion system according to claim 12, further comprising
a temperature detection part configured to detect temperature of the power storage device,
wherein the state diagnosis part is configured to correct the resistance value using a detection temperature of the temperature detection part.

17. The power conversion system according to claim 12, further comprising
an annunciation part configured to annunciate based on a diagnosis result of the state diagnosis part.

18. The power conversion system according to claim 1, further comprising
an annunciation part configured to annunciate based on a diagnosis result of the state diagnosis part.

19. A power conversion system comprising:
a first power converter configured to convert AC power from an AC power source to first DC power;
a second power converter configured to convert the first DC power from the first power converter to another second DC power having a different power value from the first DC power; and
a power storage device configured to store the second DC power from the second power converter,
the second power converter comprising:
means for performing at least one of superposition of a predetermined AC voltage on a DC voltage in the second DC power and superposition of a predetermined AC current on a DC current in the second DC power;
means for detecting at least one of a detection value of the DC voltage superposed with the AC voltage and a detection value of the DC current superposed with the AC current; and
means for diagnosing a state of the power storage device based on at least one of the detection value of the DC voltage and the detection value of the DC current.
